(19) United States
(12) Patent Application Publication
(10) Pub. No.: US 2007/0049023 A1
(43) Pub. Date: Mar. 1, 2007

(54) Zirconium-doped gadolinium oxide films

(75) Inventors: Kie Y. Ahn, Chappaqua, NY (US); Leonard Forbes, Corvallis, OR (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/215,578

(22) Filed: Aug. 29, 2005

(51) Int. Cl. H01L 21/44

(52) U.S. Cl. 438/685

(57) ABSTRACT

Electronic apparatus and methods of forming the electronic apparatus include a zirconium-doped gadolinium oxide film for use in a variety of electronic systems. The zirconium-doped gadolinium oxide film may be structured as one or more monolayers. The zirconium-doped gadolinium oxide film may be formed by atomic layer deposition.

### TECHNICAL FIELD

This application relates generally to semiconductor devices and device fabrication, and more particularly, to dielectric layers and their method of fabrication.

### BACKGROUND

The semiconductor device industry has a market driven need to reduce the size of devices used in products such as processor chips, mobile telephones, and memory devices such as dynamic random access memories (DRAMs). Currently, the semiconductor industry relies on the ability to reduce or scale the dimensions of its basic devices. This device scaling includes scaling dielectric layers in devices such as, for example, capacitors and silicon-based metal oxide semiconductor field effect transistors (MOSFETs) and variations thereof, which have primarily been fabricated using silicon dioxide. A thermally grown amorphous SiO₂ layer provides an electrically and thermodynamically stable material, where the interface of the SiO₂ layer with underlying silicon provides a high quality interface as well as superior electrical isolation properties. However, increased scaling and other requirements in microelectronic devices have created the need to use other materials as dielectric regions in a variety of electronic structures.

### SUMMARY

The abovementioned problems are addressed by the present invention and will be understood by reading and studying the following specification. An embodiment for a method includes forming a zirconium-doped gadolinium oxide film by atomic layer deposition. Embodiments include structures for capacitors, transistors, memory devices, and electronic systems with a zirconium-doped gadolinium oxide film structured as one or more monolayers, and methods for forming such structures. These and other aspects, embodiments, advantages, and features will become apparent from the following description and the referenced drawings.

### BRIEF DESCRIPTION OF THE DRAWINGS

FIG. 1 illustrates features for an embodiment of a method to form a zirconium-doped gadolinium oxide film by atomic layer deposition.

FIG. 2 shows an embodiment of a transistor having a dielectric layer containing a zirconium-doped gadolinium oxide film.

FIG. 3 shows an embodiment of a floating gate transistor having a dielectric layer containing a zirconium-doped gadolinium oxide film.

FIG. 4 shows an embodiment of a capacitor having a dielectric layer containing a zirconium-doped gadolinium oxide film.

FIG. 5 depicts an embodiment of a dielectric layer having multiple layers including a zirconium-doped gadolinium oxide layer.

FIG. 6 is a simplified diagram for an embodiment of a controller coupled to an electronic device having a dielectric layer containing a zirconium-doped gadolinium oxide film.

FIG. 7 illustrates a diagram for an embodiment of an electronic system having devices with a dielectric film containing a zirconium-doped gadolinium oxide film.

### DETAILED DESCRIPTION

The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized and structural, logical, and electrical changes may be made without departing from the scope of the present invention. The various embodiments are not necessarily mutually exclusive, as some embodiments can be combined with one or more other embodiments to form new embodiments.

The terms wafer and substrate used in the following description include any structure having an exposed surface with which to form an integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to generally include n-type and p-type semiconductors and the term insulator or dielectric is defined to include any material that is less electrically conductive than the materials referred to as conductors or as semiconductors. The following detailed description is, therefore, not to be taken in a limiting sense, and the scope of the present invention is defined only by the appended claims, along with the full scope of equivalents to which such claims are entitled.

To scale a dielectric region to minimize feature sizes to provide high density electronic devices, the dielectric region should have a reduced equivalent oxide thickness (t_{eq}). The equivalent oxide thickness quantifies the electrical properties, such as capacitance, of the dielectric in terms of a representative physical thickness. t_{eq} is defined as the thickness of a theoretical SiO₂ layer that would be required to have the same capacitance density as a given dielectric, ignoring leakage current and reliability considerations.

A SiO₂ layer of thickness, t, deposited on a silicon surface will have a t_{eq} larger than its thickness, t. This t_{eq} results from the capacitance in the surface on which the SiO₂ is deposited due to the formation of a depletion/inversion region. This depletion/inversion region can result in t_{eq} being from 3 to 6 Angstroms (Å) larger than the SiO₂ thickness, t. Thus, with the semiconductor industry driving to someday scale a gate dielectric equivalent oxide thickness to less than 10 Å, the physical thickness requirement for a SiO₂ layer used for a gate dielectric may need to be approximately 4 to 7 Å. Additional requirements on a SiO₂ layer would depend on the electrode used in conjunction with the SiO₂ dielectric. Using a conventional polysilicon electrode may result in an additional increase in t_{eq} for the SiO₂ layer. This additional thickness may be eliminated by using a metal electrode, though such metal electrodes are not universally used for all devices. Thus, designs for future devices may be directed towards a physical SiO₂ dielectric layer of about 5 Å or less. Such a small thickness requirement for a SiO₂ oxide layer creates additional problems.

Silicon dioxide is used as a dielectric layer in devices, in part, due to its electrical isolation properties in a SiO₂—Si based structure. This electrical isolation is due to the relatively large band gap of SiO₂ (8.9 eV), making it a good insulator from electrical conduction. Significant reductions in its band gap may eliminate it as a material for a dielectric region in an electronic device. As the thickness of a SiO₂ layer decreases, the number of atomic layers, or monolayers of the material decreases. At a certain thickness, the number of monolayers will be sufficiently small that the SiO₂ layer will not have a complete arrangement of atoms as in a larger or bulk layer. As a result of incomplete formation relative to a bulk structure, a thin SiO₂ layer of only one or two monolayers may not form a full band gap. The lack of a full band gap in a SiO₂ dielectric may cause an effective short between an underlying electrode and an overlying electrode. This undesirable property sets a limit on the physical thickness to which a SiO₂ layer can be scaled. The minimum thickness due to this monolayer effect is thought to be about 7-8 Å. Therefore, for future devices to have a t_{eq} less than about 10 Å, other dielectrics than SiO₂ need to be considered for use as a dielectric region in such future devices.

In many cases, for a typical dielectric layer, the capacitance is determined as one for a parallel plate capacitance: C=κε₀A/t, where κ is the dielectric constant, ε₀ is the permittivity of free space, A is the area of the capacitor, and t is the thickness of the dielectric. The thickness, t, of a material is related to its t_{eq} for a given capacitance, with SiO₂ having a dielectric constant κₒₓ=3.9, as
t=(κ/κₒₓ)t_{eq}=(κ/3.9)t_{eq}.
Thus, materials with a dielectric constant greater than that of SiO₂, 3.9, will have a physical thickness that can be considerably larger than a desired t_{eq}, while providing the desired equivalent oxide thickness. For example, an alternative dielectric material with a dielectric constant of 10 could have a thickness of about 25.6 Å to provide a t_{eq} of 10 Å, not including any depletion/inversion layer effects. Thus, a reduced equivalent oxide thickness for transistors can be realized by using dielectric materials with higher dielectric constants than SiO₂.

The thinner equivalent oxide thickness required for lower device operating voltages and smaller device dimensions may be realized by a significant number of materials, but additional fabricating requirements make determining a suitable replacement for SiO₂ difficult. The current view for the microelectronics industry is still for silicon-based devices. This may require that the dielectric material employed be grown on a silicon substrate or a silicon layer, which places significant constraints on the substitute dielectric material. During the formation of the dielectric on the silicon layer, there exists the possibility that a small layer of SiO₂ could be formed in addition to the desired dielectric. The result would effectively be a dielectric layer consisting of two sublayers in parallel with each other and the silicon layer on which the dielectric is formed. In such a case, the resulting capacitance would be that of two dielectrics in series. As a result, the t_{eq} of the dielectric layer would be the sum of the SiO₂ thickness and a multiplicative factor of the thickness, t, of the dielectric being formed, written as
t_{eq}=t_{SiO2}+(κₒₓ/κ)t.
Thus, if a SiO₂ layer is formed in the process, the t_{eq} is again limited by a SiO₂ layer. In the event that a barrier layer is formed between the silicon layer and the desired dielectric in which the barrier layer prevents the formation of a SiO₂ layer, the t_{eq} would be limited by the layer with the lowest dielectric constant. However, whether a single dielectric layer with a high dielectric constant or a barrier layer with a higher dielectric constant than SiO₂ is employed, the layer interfacing with the silicon layer should provide a high quality interface.

One of the advantages of using SiO₂ as a dielectric layer in a device has been that the formation of the SiO₂ layer results in an amorphous dielectric. Having an amorphous structure for a dielectric provides for reducing problems of leakage current associated with grain boundaries in polycrystalline dielectrics that provide high leakage paths. Additionally, grain size and orientation changes throughout a polycrystalline dielectric can cause variations in the film's dielectric constant, along with uniformity and surface topography problems. Typically, materials having a high dielectric constant relative to SiO₂ also have a crystalline form, at least in a bulk configuration. The best candidates for replacing SiO₂ as a dielectric in a device are those that can be fabricated as a thin layer with an amorphous form and that have high dielectric constants.

In an embodiment, a film of gadolinium oxide doped with zirconium may be used as a dielectric layer for application in a variety of electronic devices, replacing the use of silicon oxide to provide a higher dielectric constant for the given dielectric layer. A film of Gd₂O₃ may provide a dielectric layer having a dielectric constant in the range from about 12 to about 16. In addition, Gd₂O₃ may provide a close lattice match for a silicon layer on which it may be disposed. A film of ZrO₂ may provide a dielectric layer having a dielectric constant of about 25. Incorporating zirconium into a gadolinium oxide film may increase the dielectric constant of the associated film. During processing of a gadolinium layer on a silicon surface, where the gadolinium layer is formed without zirconium dopants, a silicate interface layer may form. Incorporation of zirconium in the gadolinium layer may suppress or reduce the formation of such a silicate interface layer. In an embodiment, a zirconium-doped gadolinium oxide layer may have a zirconium content such that the highest content of zirconium in the zirconium-doped gadolinium layer occurs near the interface of the gadolinium oxide layer and the material on which it is disposed.

Another consideration for selecting the material and method for forming a dielectric film for use in electronic devices and systems concerns the roughness of a dielectric film on a substrate. Surface roughness of the dielectric film has a significant effect on the electrical properties of the gate oxide, and the resulting operating characteristics of the transistor. The leakage current through a physical 1.0 nm gate oxide increases by a factor of 10 for every 0.1 increase in the root-mean-square (RMS) roughness.

During a conventional sputtering deposition process stage, particles of the material to be deposited bombard the surface at a high energy. When a particle hits the surface, some particles adhere, and other particles cause damage. High energy impacts remove body region particles, creating pits. The surface of such a deposited layer can have a rough contour due to the rough interface at the body region.

In an embodiment, a zirconium-doped gadolinium oxide dielectric film having a substantially smooth surface relative to other processing techniques is formed using atomic layer deposition (ALD). Further, forming such a dielectric film using atomic layer deposition can provide for controlling transitions between material layers. As a result of such control, atomic layer deposited zirconium-doped gadolinium oxide dielectric films can have an engineered transition with a substrate surface.

ALD, also known as atomic layer epitaxy (ALE), is a modification of chemical vapor deposition (CVD) and is also called “alternatively pulsed-CVD.” In ALD, gaseous precursors are introduced one at a time to the substrate surface mounted within a reaction chamber (or reactor). This introduction of the gaseous precursors takes the form of pulses of each gaseous precursor. In a pulse of a precursor gas, the precursor gas is made to flow into a specific area or region for a short period of time. Between the pulses, the reaction chamber may be purged with a gas, where the purging gas may be an inert gas. Between the pulses, the reaction chamber may be evacuated. Between the pulses, the reaction chamber may be purged with a gas and evacuated.

In a chemisorption-saturated ALD (CS-ALD) process, during the first pulsing phase, reaction with the substrate occurs with the precursor saturatively chemisorbed at the substrate surface. Subsequent pulsing with a purging gas removes precursor excess from the reaction chamber.

The second pulsing phase introduces another precursor on the substrate where the growth reaction of the desired film takes place. Subsequent to the film growth reaction, reaction byproducts and precursor excess are purged from the reaction chamber. With favourable precursor chemistry where the precursors adsorb and react with each other aggressively on the substrate, one ALD cycle can be performed in less than one second in properly designed flow type reaction chambers. Typically, precursor pulse times range from about 0.5 sec to about 2 to 3 seconds. Pulse times for purging gases may be significantly larger, for example, pulse times of about 5 to about 30 seconds.

In ALD, the saturation of all the reaction and purging phases makes the growth self-limiting. This self-limiting growth results in large area uniformity and conformality, which has important applications for such cases as planar substrates, deep trenches, and in the processing of porous silicon and high surface area silica and alumina powders. Significantly, ALD provides for controlling film thickness in a straightforward manner by controlling the number of growth cycles.

The precursors used in an ALD process may be gaseous, liquid or solid. However, liquid or solid precursors should be volatile. The vapor pressure should be high enough for effective mass transportation. Also, solid and some liquid precursors may need to be heated inside the reaction chamber and introduced through heated tubes to the substrates. The necessary vapor pressure should be reached at a temperature below the substrate temperature to avoid the condensation of the precursors on the substrate. Due to the self-limiting growth mechanisms of ALD, relatively low vapor pressure solid precursors can be used, though evaporation rates may vary somewhat during the process because of changes in their surface area.

There are several other characteristics for precursors used in ALD. The precursors should be thermally stable at the substrate temperature, because their decomposition may destroy the surface control and accordingly the advantages of the ALD method that relies on the reaction of the precursor at the substrate surface. A slight decomposition, if slow compared to the ALD growth, may be tolerated.

The precursors should chemisorb on or react with the surface, though the interaction between the precursor and the surface as well as the mechanism for the adsorption is different for different precursors. The molecules at the substrate surface should react aggressively with the second precursor to form the desired solid film. Additionally, precursors should not react with the film to cause etching, and precursors should not dissolve in the film. Using highly reactive precursors in ALD contrasts with the selection of precursors for conventional CVD.

The by-products in the reaction should be gaseous in order to allow their easy removal from the reaction chamber. Further, the by-products should not react or adsorb on the surface.

In a reaction sequence ALD (RS-ALD) process, the self-limiting process sequence involves sequential surface chemical reactions. RS-ALD relies on chemistry between a reactive surface and a reactive molecular precursor. In an RS-ALD process, molecular precursors are pulsed into the ALD reaction chamber separately. A metal precursor reaction at the substrate is typically followed by an inert gas pulse to remove excess precursor and by-products from the reaction chamber prior to pulsing the next precursor of the fabrication sequence.

By RS-ALD, films can be layered in equal metered sequences that may all be identical in chemical kinetics, deposition per cycle, composition, and thickness. RS-ALD sequences generally deposit less than a full layer per cycle. Typically, a deposition or growth rate of about 0.25 to about 2.00 Å per RS-ALD cycle may be realized.

Processing by RS-ALD provides continuity at an interface avoiding poorly defined nucleating regions that are typical for chemical vapor deposition (<20 Å) and physical vapor deposition (<50 Å), conformality over a variety of substrate topologies due to its layer-by-layer deposition technique, use of low temperature and mildly oxidizing processes, lack of dependence on the reaction chamber, growth thickness dependent solely on the number of cycles performed, and ability to engineer multilayer laminate films with a resolution of one to two monolayers. RS-ALD processes allow for deposition control on the order of monolayers and the ability to deposit monolayers of amorphous films.

Herein, a sequence refers to the ALD material formation based on an ALD reaction of a precursor with its reactant precursor. For example, forming zirconium oxide from a ZrI₄ precursor and water vapor, as its reactant precursor, forms an embodiment of an zirconium/oxygen sequence, which can also be referred to as a zirconium sequence. In various ALD processes that form an oxide or a compound that contains oxygen, a reactant precursor that contains oxygen is used to supply oxygen. Herein, a precursor that contains oxygen and that supplies oxygen to be incorporated in the ALD compound formed, which may be used in an ALD process with precursors supplying the other elements in the ALD compound, is referred to as an oxygen reactant precursor. In the above example, water vapor is an oxygen reactant precursor. A cycle of a sequence may include pulsing a precursor, pulsing a purging gas for the precursor, pulsing a reactant precursor, and pulsing the reactant precursor's purging gas. Further, in forming a layer of a metal species, an ALD sequence may deal with reacting a precursor containing the metal species with a substrate surface, depending on the particular precursor used. A cycle for such a metal forming sequence may include pulsing a purging gas after pulsing the precursor containing the metal species to deposit the metal. Additionally, deposition of a semiconductor material may be realized in a manner similar to forming a layer of a metal, given the appropriate precursors for the semiconductor material.

In an ALD formation of a compound having more than two elements, a cycle may include a number of sequences to provide the elements of the compound. For example, a cycle for an ALD formation of an ABOₓ compound may include sequentially pulsing a first precursor/a purging gas for the first precursor/a first reactant precursor/the first reactant precursor's purging gas/a second precursor/a purging gas for the second precursor/a second reactant precursor/the second reactant precursor's purging gas, which may be viewed as a cycle having two sequences. In an embodiment, a cycle may include processing a number of sequences for element A and a different number of sequences for element B. There may be cases in which ALD formation of an ABOₓ compound uses one precursor that contains the elements A and B, such that pulsing the AB containing precursor followed by its reactant precursor onto a substrate may include a reaction that deposits ABOₓ on the substrate to provide an AB/oxygen sequence. A cycle of an AB/oxygen sequence may include pulsing a precursor containing A and B, pulsing a purging gas for the precursor, pulsing a reactant precursor to the A/B precursor, and pulsing a purging gas for the reactant precursor. A cycle may be repeated a number of times to provide a desired thickness of the compound. In an embodiment, a layer of zirconium-doped gadolinium oxide is formed on a substrate mounted in a reaction chamber using ALD in repetitive gadolinium and zirconium sequences using precursor gases individually pulsed into the reaction chamber. Alternatively, solid or liquid precursors can be used in an appropriately designed reaction chamber.

In an embodiment, a zirconium-doped gadolinium oxide layer may be structured as one or more monolayers. A film of zirconium-doped gadolinium oxide, structured as one or more monolayers, may have a thickness that ranges from a monolayer to thousands of angstroms. The film may be processed by atomic layer deposition. Embodiments of an atomic layer deposited zirconium-doped gadolinium oxide layer have a larger dielectric constant than silicon dioxide. Such dielectric layers provide a significantly thinner equivalent oxide thickness compared with a silicon oxide layer having the same physical thickness. Alternatively, such dielectric layers provide a significantly thicker physical thickness than a silicon oxide layer having the same equivalent oxide thickness. This increased physical thickness aids in reducing leakage current.

The term gadolinium oxide is used herein with respect to a compound that essentially consists of gadolinium and oxygen in a form that may be stoichiometric, non-stoichiometric, or a combination of stoichiometric and non-stoichiometric. Herein, gadolinium oxide may be expressed as GdOₓ. The expression GdOₓ or its equivalent forms may be used to include a stoichiometric gadolinium oxide. The expression GdOₓ or its equivalent forms may be used to include a non-stoichiometric gadolinium oxide. The expression GdOₓ or its equivalent forms may be used to include a combination of a stoichiometric gadolinium oxide and a non-stoichiometric gadolinium oxide. In an embodiment, a gadolinium oxide film includes Gd₂O₃. The expression ZrOₓ may be used to include a stoichiometric zirconium oxide. The expression ZrOₓ may be used to include a non-stoichiometric zirconium oxide. The expression ZrOₓ may be used to include a combination of a stoichiometric zirconium oxide and a non-stoichiometric zirconium oxide. In various embodiments, a gadolinium oxide film may be doped with zirconium. In an embodiment, a Zr-doped GdOₓ layer may be formed by atomic layer deposition. The Zr-doped GdOₓ layer may be processed to have a specific zirconium content. The Zr-doped GdOₓ layer may be processed to have a specific profile of zirconium content across the thickness of the gadolinium layer (relative to the surface on which the gadolinium layer is deposited).

In an embodiment, a Zr-doped GdOₓ film may be constructed as one or more monolayers by atomic layer deposition. Prior to forming the Zr-doped GdOₓ by ALD, the surface on which the Zr-doped GdOₓ is to be deposited may undergo a preparation stage. The surface may be the surface of a substrate for an integrated circuit. In an embodiment, the substrate used for forming a transistor includes a silicon or silicon-containing material. In other embodiments, germanium, gallium arsenide, silicon-on-sapphire substrates, or other suitable substrates may be used. A preparation process may include cleaning the substrate and forming layers and regions of the substrate, such as drains and sources, prior to forming a gate dielectric in the formation of a metal oxide semiconductor (MOS) transistor. Alternatively, active regions may be formed after forming the dielectric layer, depending on the over-all fabrication process implemented. In an embodiment, the substrate is cleaned to provide an initial substrate depleted of its native oxide. In an embodiment, the initial substrate is cleaned also to provide a hydrogen-terminated surface. In an embodiment, a silicon substrate undergoes a final hydrofluoric (HF) rinse prior to ALD processing to provide the silicon substrate with a hydrogen-terminated surface without a native silicon oxide layer. Cleaning immediately preceding atomic layer deposition aids in reducing an occurrence of silicon oxide as an interface between a silicon-based substrate and a zirconium-doped gadolinium oxide dielectric formed using the atomic layer deposition process. The material composition of an interface layer and its properties are typically dependent on process conditions and the condition of the substrate before forming the dielectric layer. Though the existence of an interface layer may effectively reduce the dielectric constant associated with the dielectric layer and its substrate interface layer, a SiO₂ interface layer or other composition interface layer, may improve the interface density, fixed charge density, and channel mobility of a device having this interface layer.

The sequencing of the formation of the regions of an electronic device, such as a transistor, being processed may follow typical sequencing that is generally performed in the fabrication of such devices as is well known to those skilled in the art. Included in the processing prior to forming a dielectric may be the masking of substrate regions to be protected during the dielectric formation, as is typically performed in semiconductor fabrication. In an embodiment, the unmasked region includes a body region of a transistor; however, one skilled in the art will recognize that other semiconductor device structures may utilize this process.

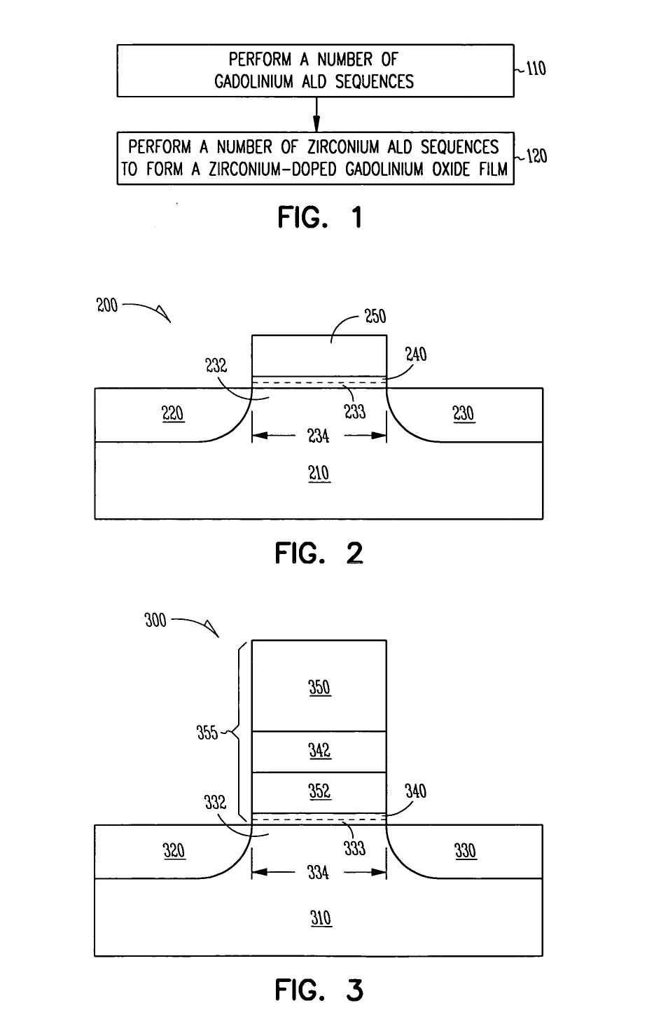

FIG. 1 illustrates features of an embodiment of a method to form a zirconium-doped gadolinium oxide film by atomic layer deposition. The individual features labeled 110 and 120 may be performed in various orders. Between each pulsing of a precursor used in the atomic layer deposition process, a purging gas may be pulsed into the ALD reaction chamber. Between each pulsing of a precursor, the ALD reactor chamber may be evacuated using vacuum techniques as is known by those skilled in the art. Between each pulsing of a precursor, a purging gas may be pulsed into the ALD reaction chamber and the ALD reactor chamber may be evacuated.

At 110, a number of gadolinium ALD sequences may be performed. In one or more sequences, the pulsing of a gadolinium precursor may use a pulsing period that provides uniform coverage of a monolayer on the surface or may use a pulsing period that provides partial formation of a monolayer on the surface during a gadolinium sequence. At 120, a number of zirconium ALD sequences may be performed. In one or more sequences, the pulsing of a zirconium precursor may use a pulsing period that provides uniform coverage of a monolayer on the surface or may use a pulsing period that provides partial formation of a monolayer on the surface during a zirconium sequence. In an embodiment, a reactant precursor may be pulsed after each pulsing of the gadolinium-containing precursor to form GdOₓ, and another reactant precursor may be pulsed after each pulsing of the zirconium-containing precursor to dope the GdOₓ with ZrOₓ. The two reactant precursors may have a common composition. In an embodiment, to provide zirconium atom doping, deposition of zirconium may be followed by another pulsing of the gadolinium-containing precursor rather than by pulsing a reactant precursor. A reactant precursor to provide an oxidizing precursor may be pulsed after gadolinium and zirconium are provided to the substrate surface. Appropriate purging pulses are performed between the pulsing of each element-bearing precursor and each reactant precursor. The pulsing of the gadolinium and zirconium precursors may be regulated to provide a selected ratio of zirconium atoms to the sum of gadolinium and zirconium atoms to provide a desired doping. In an embodiment, a zirconium sequence may be substituted periodically for a gadolinium sequence. Periodic substitution may provide uniform zirconium doping of a gadolinium oxide layer. In an embodiment, substitution of a zirconium sequence for a gadolinium sequence may be varied. Varied substitution may provide zirconium doping of a gadolinium oxide layer that has varied zirconium content throughout the gadolinium oxide layer. The varied zirconium content may be selected to have a desired profile.

Forming a GdOₓ film having a zirconium dopant by atomic layer deposition may include using a number of gadolinium sequences significantly in excess of the number of zirconium cycles used for a cycle. In an embodiment, the number of gadolinium sequences may be more than five times the number of zirconium sequences. Embodiments for methods for forming zirconium-doped gadolinium oxide film by atomic layer deposition may include numerous permutations of gadolinium sequences and zirconium sequences for forming the zirconium-doped gadolinium oxide film. In an embodiment, a zirconium sequence is conducted before a gadolinium sequence. In an embodiment, a gadolinium sequence is conducted before a zirconium sequence. In an embodiment, a gadolinium/zirconium cycle may include a number, x, of gadolinium sequences, and a number, y, of zirconium sequences. The number of sequences x and y may be selected to engineer the relative amounts of zirconium to gadolinium to provide a desired zirconium doping. In an embodiment, the number of sequences x and y, along with associated pulsing periods and times, is selected to form a Zr-doped gadolinium oxide film with a zirconium content of 10% or less. In an embodiment, the number of sequences x and the number of sequences y, along with associated pulsing periods and times, are selected to form an essentially Gd₂O₃ film having a zirconium doping to maintain characteristics of a Gd₂O₃ film. In various embodiments, the number of sequences x and the number of sequences y, along with associated pulsing periods and times, are selected to form an GdOₓ film having a zirconium doping to provide enhanced characteristics for the gadolinium oxide, for instance, a larger dielectric constant.

An ALD cycle may contain variations of gadolinium sequences and zirconium sequences. In an embodiment, an ALD cycle may include x gadolinium sequences followed by y zirconium sequences followed by z gadolinium sequences. In various embodiments, an ALD cycle may include any number of gadolinium and zirconium sequences in which the number of gadolinium sequences and the number of zirconium sequences may each be partitioned into sub-groups of sequences, with the sub-groups for gadolinium arranged in various orders with the sub-groups for zirconium. Once an ALD cycle is determined, a growth rate per cycle may be determined. As can be understood by those skilled in the art, particular growth rates can be determined during normal initial testing of the ALD system for processing a Zr-doped GdOₓ dielectric film for a given application without undue experimentation.

In an embodiment, a zirconium-containing precursor may be pulsed during a portion of the time that a gadolinium-containing precursor is being pulsed. The zirconium-containing precursor and the gadolinium-containing precursor may be non-reactive with respect to each other. A reactant precursor may provide an oxidizing reaction at the substrate surface to form GdOₓ doped with zirconium. The zirconium dopant may be ZrOₓ. In an embodiment, a zirconium-containing precursor can be pulsed simultaneously with a gadolinium-containing precursor. Then, following a gas purge, a reactant precursor that provides an ALD reaction for both the gadolinium-containing precursor and the zirconium-containing precursor may be pulsed into the reaction. The percentage of the zirconium may be controlled by regulating the percentage of the zirconium-containing precursor in the precursor mixture that is injected into the reaction chamber to the substrate. The growth per cycle would then depend on the growth rate using the given mixture. As can be understood by those skilled in the art, determining the growth rate for a particular mixture can be determined during normal initial testing of the ALD system for processing a Zr-doped GdOₓ dielectric film without undue experimentation.

After repeating a number of ALD cycles, a determination may be made as to whether the number of gadolinium/zirconium cycles equals a predetermined number to form the desired zirconium-doped gadolinium oxide layer. If the total number of cycles to form the desired thickness has not been completed, a number of cycles for the gadolinium and zirconium sequences may be repeated. If the total number of cycles to form the desired thickness has been completed, a dielectric film containing the zirconium-doped gadolinium oxide layer may optionally be annealed. The zirconium-doped gadolinium oxide layer processed at these relatively low temperatures may provide an amorphous layer.

The thickness of a zirconium-doped gadolinium oxide layer formed by atomic layer deposition may be determined by a fixed growth rate for the pulsing periods and precursors used, set at a value such as N nm/cycle, dependent upon the number of cycles of the gadolinium/zirconium sequences. For a desired zirconium-doped gadolinium oxide layer thickness, t, in an application, the ALD process is repeated for t/N total cycles. Once the t/N cycles have completed, no further ALD processing for the zirconium-doped gadolinium oxide layer may be required.

In an embodiment, a zirconium-doped gadolinium oxide film may be formed as an arrangement of zirconium-doped gadolinium oxide layers. Each zirconium-doped gadolinium oxide layer in the arrangement may have a different zirconium content than the other layers in the arrangement. In an embodiment, at least one zirconium-doped gadolinium oxide layer has a zirconium content different from the other zirconium-doped gadolinium oxide layers of the arrangement. In an embodiment, an arrangement of zirconium-doped gadolinium oxide layers may be formed with the layer having the highest zirconium content formed contacting a surface on which the Zr-doped GdOₓ film is being deposited. In various embodiments, the zirconium content may be varied among the zirconium-doped gadolinium oxide layers of the arrangement constructed as a zirconium-doped gadolinium oxide film. A zirconium-doped gadolinium oxide film may be constructed having an engineered profile of zirconium content across the thickness of the film. The multi-layer arrangement for a Zr-doped GdOₓ film may be formed by atomic layer deposition. In an embodiment, a zirconium-doped gadolinium oxide film may be formed having a dielectric constant in the range from about 15 to about 25.

In various embodiments, a gadolinium-containing precursor may be pulsed onto a substrate in an ALD reaction chamber. A number of precursors containing gadolinium may be used to provide gadolinium to the substrate for an integrated circuit. The gadolinium-containing precursor may be pulsed to a silicon substrate having a specific orientation. In an embodiment, a gadolinium-containing precursor may be pulsed to a silicon (100) substrate. In an embodiment, the gadolinium-containing precursor may be Gd(thd)₃ (thd=2,2,6,6-tetramethyl-3,5-heptanedione). In an embodiment using a Gd(thd)₃ precursor, the substrate may be maintained at a temperature of about 300° C. The ALD chamber may be at pressure between about 2 mbar and 3 mbar. After pulsing the gadolinium-containing precursor and purging the reaction chamber of excess precursor and by-products from pulsing the precursor, a reactant precursor may be pulsed into the reaction chamber. The reactant precursor may be an oxygen reactant precursor. In an embodiment, ozone may be used as an oxygen reactant precursor in a gadolinium sequence using Gd(thd)₃. In various embodiments, use of the individual gadolinium-containing precursors is not limited to the temperature range or pressure range of the above embodiment. In addition, the pulsing of the gadolinium-containing precursor may use a pulsing period that provides uniform coverage of a monolayer on the surface or may use a pulsing period that provides partial formation of a monolayer on the surface during an gadolinium sequence.

A number of precursors containing zirconium may be used to provide zirconium as a dopant for a GdOₓ film. In an embodiment, a precursor containing zirconium may include tetrakis(diethylamino) zirconium (TDEAZ). Oxygen may be used as its reactant precursor in a zirconium sequence, with argon gas used as a pulsing gas after TDEAZ pulses and oxygen pulses. Various pulse times may be used in the zirconium/oxygen sequence including using equal pulse times, for example, using 5 seconds as a common pulse time. In an embodiment, oxygen plasma may be used as a reactant precursor. In an embodiment, the substrate temperature may be maintained at about 350° C.

In an embodiment, a precursor containing zirconium may include a zirconium halide precursor. ZrCl₄ may be used as a zirconium precursor. Water vapor may be used as a oxygen reactant precursor. In an embodiment, the substrate temperature may be maintained at about 300° C. Other zirconium halides, such as ZrI₄, may be used as a zirconium precursor in an ALD process.

In an embodiment, a zirconium-containing precursor may include zirconium tertiary-butoxide, Zr(t-OC₄H₉)₄ (ZTB). Water vapor may be used as a reactant precursor in a zirconium sequence. Oxygen plasma may be used as a reactant precursor in a zirconium sequence. Various pulse times may be used in the zirconium/oxygen sequence including using equal pulse times. ALD using ZTB may use longer pulse times, for example, pulse times in the range from 10 seconds to about 180 seconds. An inert gas may be used as a purging gas. In an embodiment, the substrate temperature may be maintained at a temperature ranging from about 75° C. to about 400° C. However, use of the individual zirconium-containing precursors is not limited to the temperature ranges of embodiments described herein. In addition, the pulsing of the zirconium-containing precursor may use a pulsing period that provides uniform coverage of a monolayer on the surface or may use a pulsing period that provides partial formation of a monolayer on the surface during a zirconium sequence.

Various oxygen-containing precursors may be used as oxygen reactant precursors for each of a gadolinium sequence and a zirconium sequence. Oxygen reactant precursors for the ALD formation of a Zr-doped GdOₓ film may include, but are not limited to, one or more of water, atomic oxygen, molecular oxygen, ozone, hydrogen peroxide, a water-hydrogen peroxide mixture, alcohol, nitrous oxide, a hydrogen plasma, or an oxygen plasma. In various embodiments, nitrogen may be used as a purging gas and a carrier gas for one or more of the sequences used in the ALD formation of a Zr-doped GdOₓ film. Alternatively, hydrogen, argon, or other, inert gases may be used as the purging gas. Excess precursor gas and reaction by-products may be removed by the purging gas. Excess precursor gas and reaction by-products may be removed by evacuation of the reaction chamber using various vacuum techniques. Excess precursor gas and reaction by-products may be removed by the purging gas and by evacuation of the reaction chamber.

Atomic layer deposition of the individual components of the zirconium-doped gadolinium oxide film allows for individual control of each precursor pulsed into the reaction chamber. Thus, each precursor is pulsed into the reaction chamber for a predetermined period, where the predetermined period can be set separately for each precursor. Additionally, for various embodiments for ALD formation of a Zr-doped GdOₓ film, each precursor may be pulsed into the reaction under separate environmental conditions. The substrate may be maintained at a selected temperature and the reaction chamber maintained at a selected pressure independently for pulsing each precursor. Appropriate temperatures and pressures may be maintained, whether the precursor is a single precursor or a mixture of precursors.

Films of Zr-doped GdOₓ may be processed over a wide range of temperatures. Low temperature processing may lead to an amorphous structure and have fewer adverse effects on the substrate and any devices formed prior to the ALD formation of the zirconium-doped gadolinium oxide film. In an embodiment, a film of Zr-doped GdOₓ is formed on a substrate with the substrate maintained at a temperature in the range from about 100° C. to about 600° C. The zirconium-doped gadolinium oxide film may be formed as an integral component of an electronic device in an integrated circuit.

Either before or after forming the zirconium-doped gadolinium oxide film, other dielectric layers such as nitride layers, dielectric metal silicates, insulating metal oxides including undoped Gd₂O₃, ZrO₂, La₂O₃, and other lanthanide oxides such as Pr₂O₃, Nd₂O₃, Sm₂O₃, Dy₂O₃, Ce₂O₃, Tb₂O₃, Er₂O₃, Eu₂O₃, Lu₂O₃, Tm₂O₃, Ho₂O₃, Pm₂O₃, and Yb₂O₃ or combinations thereof may be formed as part of a dielectric layer or dielectric stack. These one or more other layers of dielectric material may be provided in stoichiometric form, in non-stoichiometric form, or a combination of stoichiometric dielectric material and non-stoichiometric dielectric material. Depending on the application, a dielectric stack containing a zirconium-doped gadolinium oxide film may include a silicon oxide layer. In an embodiment, the dielectric layer may be formed as a nanolaminate. An embodiment of a nanolaminate may include a layer of undoped GdOₓ and a Zr-doped GdOₓ film, a layer of ZrOₓ and a Zr-doped GdOₓ film, layers of undoped GdOₓ and ZrOₓ along with a Zr-doped GdOₓ film, or various other combinations. Alternatively, a dielectric layer may be formed substantially as the zirconium-doped gadolinium oxide film.

In various embodiments, the structure of an interface between a dielectric layer and a substrate on which it is disposed is controlled to limit the inclusion of silicon oxide, since a silicon oxide layer would reduce the effective dielectric constant of the dielectric layer. The material composition and properties for an interface layer may be dependent on process conditions and the condition of the substrate before forming the dielectric layer. Though the existence of an interface layer may effectively reduce the dielectric constant associated with the dielectric layer and its substrate, the interface layer, such as a silicon oxide interface layer or other composition interface layer, may improve the interface density, fixed charge density, and channel mobility of a device having this interface layer.

In the various embodiments, the thickness of a zirconium-doped gadolinium oxide film is related to the number of ALD cycles performed and the growth rate associated with the selected permutations of sequences in the cycles. As can be understood by those skilled in the art, particular effective growth rates for the engineered zirconium-doped gadolinium oxide film can be determined during normal initial testing of the ALD system for processing a zirconium-doped gadolinium oxide dielectric for a given application without undue experimentation.,

In an embodiment, a dielectric layer containing a zirconium-doped gadolinium oxide layer may have a t_{eq} ranging from about 5 Å to about 20 Å. In an embodiment, a dielectric layer containing a zirconium-doped gadolinium oxide layer may have a t_{eq} of less than 5 Å. In an embodiment, a zirconium-doped gadolinium oxide film may be formed with a thickness ranging from a monolayer to thousands of angstroms. Further, dielectric films of zirconium-doped gadolinium oxide formed by atomic layer deposition may provide not only thin t_{eq} films, but also films with relatively low leakage current. Additionally, embodiments may be implemented to form transistors, capacitors, memory devices, and other electronic systems including information handling devices.

FIG. 2 shows an embodiment of a transistor 200 having a dielectric layer 240 containing a zirconium-doped gadolinium oxide film. Transistor 200 may include a source region 220 and a drain region 230 in a silicon-based substrate 210, where source and drain regions 220, 230 are separated by a body region 232. Body region 232 defines a channel having a channel length 234. A gate dielectric 240 may be disposed on substrate 210, with gate dielectric 240 formed as a dielectric layer containing zirconium-doped gadolinium oxide. Gate dielectric 240 may be realized as a dielectric layer formed substantially of zirconium-doped gadolinium oxide. Gate dielectric 240 may be a dielectric stack containing at least one zirconium-doped gadolinium oxide film and one or more layers of insulating material other than a zirconium-doped gadolinium oxide film. The zirconium-doped gadolinium oxide may be structured as one or more monolayers. An embodiment of a zirconium-doped gadolinium oxide film may be formed by atomic layer deposition. In an embodiment, a gate 250 may be formed over and contact gate dielectric 240.

An interfacial layer 233 may form between body region 232 and gate dielectric 240. Interfacial layer 233 may be a silicon oxide layer, a silicate layer, or a combination of a silicon oxide and silicate layer. In an embodiment, interfacial layer 233 may be limited to a relatively small thickness compared to gate dielectric 240, or to a thickness significantly less than gate dielectric 240 as to be effectively eliminated. Forming the substrate and the source and drain regions may be performed using standard processes known to those skilled in the art. Additionally, the sequencing of the various elements of the process for forming a transistor may be conducted with fabrication processes known to those skilled in the art. In an embodiment, gate dielectric 240 may be realized as a gate insulator in a silicon complementary metal-oxide-semiconductor field effect transistor (CMOS). Use of a gate dielectric containing zirconium-doped gadolinium oxide is not limited to silicon-based substrates, but may be used with a variety of semiconductor substrates.

FIG. 3 shows an embodiment of a floating gate transistor 300 having a dielectric layer containing a zirconium-doped gadolinium oxide film. The Zr-doped GdOₓ film may be structured as one or more monolayers. The Zr-doped GdOₓ film may be formed using atomic layer deposition techniques. Transistor 300 may include a silicon-based substrate 310 with a source 320 and a drain 330 separated by a body region 332. Body region 332 between source 320 and drain 330 defines a channel region having a channel length 334. Located above body region 332 is a stack 355 including a gate dielectric 340, a floating gate 352, a floating gate dielectric 342, and a control gate 350. An interfacial layer 333 may form between body region 332 and gate dielectric 340. In an embodiment, interfacial layer 333 may be limited to a relatively small thickness compared to gate dielectric 340, or to a thickness significantly less than gate dielectric 340 as to be effectively eliminated.

In an embodiment, gate dielectric 340 includes a dielectric containing an atomic layer deposited Zr-doped GdOₓ film formed in embodiments similar to those described herein. Gate dielectric 340 may be realized as a dielectric layer formed substantially of Zr-doped GdOₓ. Gate dielectric 340 may be a dielectric stack containing at least one Zr-doped GdOₓ film and one or more layers of insulating material other than a zirconium-doped gadolinium oxide film. In an embodiment, floating gate 352 may be formed over and contact gate dielectric 340.

In an embodiment, floating gate dielectric 342 includes a dielectric containing a zirconium-doped gadolinium oxide film. The Zr-doped GdOₓ film may be structured as one or more monolayers. In an embodiment, the Zr-doped GdOₓ may be formed using atomic layer deposition techniques. Floating gate dielectric 342 may be realized as a dielectric layer formed substantially of Zr-doped GdOₓ. Floating gate dielectric 342 may be a dielectric stack containing at least one Zr-doped GdOₓ film and one or more layers of insulating material other than a Zr-doped GdOₓ film. In an embodiment, control gate 350 may be formed over and contact floating gate dielectric 342.

Alternatively, both gate dielectric 340 and floating gate dielectric 342 may be formed as dielectric layers containing a Zr-doped GdOₓ film structured as one or more monolayers. Gate dielectric 340 and floating gate dielectric 342 may be realized by embodiments similar to those described herein, with the remaining elements of the transistor 300 formed using processes known to those skilled in the art. In an embodiment, gate dielectric 340 forms a tunnel gate insulator and floating gate dielectric 342 forms an inter-gate insulator in flash memory devices, where gate dielectric 340 and floating gate dielectric 342 may include a Zr-doped GdOₓ film structured as one or more monolayers. Such structures are not limited to silicon-based substrates, but may be used with a variety of semiconductor substrates.

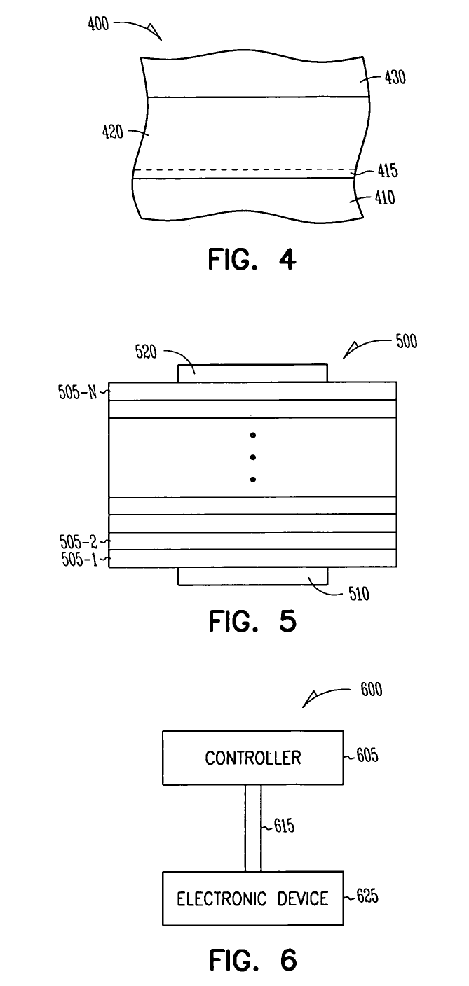

Embodiments of a zirconium-doped gadolinium oxide film structured as one or more monolayers may also be applied to capacitors in various integrated circuits, memory devices, and electronic systems. In an embodiment for a capacitor 400 illustrated in FIG. 4, a method includes forming a first conductive layer 410, forming a dielectric layer 420 containing a zirconium-doped gadolinium oxide film structured as one or more monolayers on first conductive layer 410, and forming a second conductive layer 430 on dielectric layer 420. The zirconium-doped gadolinium oxide film of dielectric layer 420 may be formed using various embodiments described herein. Dielectric layer 420 may be realized as a dielectric layer formed substantially of zirconium-doped gadolinium oxide. Dielectric layer 420 may be a dielectric stack containing at least one zirconium-doped gadolinium oxide film and one or more layers of insulating material other than a zirconium-doped gadolinium oxide film. An interfacial layer 415 may form between first conductive layer 410 and dielectric layer 420. In an embodiment, interfacial layer 415 may be limited to a relatively small thickness compared to dielectric layer 420, or to a thickness significantly less than dielectric layer 420 as to be effectively eliminated.

Embodiments for a zirconium-doped gadolinium oxide film structured as one or more monolayers may include, but are not limited to, a capacitor in a DRAM and capacitors in analog, radio frequency (RF), and mixed signal integrated circuits. Mixed signal integrated circuits are integrated circuits that may operate with digital and analog signals.

FIG. 5 depicts an embodiment of a dielectric structure 500 having multiple dielectric layers 505-1, 505-2, . . . 505-N, in which at least one layer is a zirconium-doped gadolinium oxide layer. Layers 510 and 520 may provide means to contact dielectric layers 505-1,505-2, . . . 505-N. Layers 510 and 520 may be electrodes forming a capacitor. Layer 510 may be a body region of a transistor with layer 520 being a gate. Layer 510 may be a floating gate electrode with layer 520 being a control gate.

In an embodiment, each layer 505-1, 505-2 . . . 505-N may be a Zr-doped GdOₓ layer. At least one of the layers 505-1, 505-2 . . . 505-N may have a zirconium content that is different from the zirconium content of the other layers. In an embodiment, no two of layers 505-1, 505-2 . . . 505-N have the same zirconium content. Each Zr-doped GdOₓ layer 505-1, 505-2 . . . 505-N may be formed by atomic layer deposition. The zirconium content may be varied between the different layers 505-1, 505-2 . . . 505-N by using different ALD cycles in the formation of these layers. In an embodiment, each layer may be formed substantially as Gd₂O₃ doped with zirconium, where the amount of zirconium is selected to be different in each layer 505-1, 505-2, . . . 505-N.

In an embodiment, dielectric structure 500 includes one or more layers of 505-1, 505-2, . . . 505-N as dielectric layers other than a Zr-doped GdOₓ layer, where at least one layer is a Zr-doped GdOₓ layer. Dielectric layers 505-1, 505-2, . . . 505-N may include an undoped GdOₓ layer. Dielectric layers 505-1, 505-2, . . . 505-N may include a ZrOₓ layer. Dielectric layers 505-1, 505-2 . . . 505-N may include an insulating metal oxide layer, whose metal is selected to be a metal different from gadolinium and zirconium. Dielectric layers 505-1, 505-2 . . . 505-N may include an insulating nitride layer. Dielectric layers 505-1, 505-2 . . . 505-N may include an insulating oxynitride layer. Dielectric layers 505-1, 505-2 . . . 505-N may include a silicon nitride layer. Dielectric layers 505-1, 505-2 . . . 505-N may include an insulating silicate layer. Dielectric layers 505-1, 505-2 . . . 505-N may include a silicon oxide layer.

Various embodiments for a dielectric layer containing a zirconium-doped gadolinium oxide film structured as one or more monolayers may provide for enhanced device performance by providing devices with reduced leakage current. Such improvements in leakage current characteristics may be attained by forming one or more layers of a zirconium-doped gadolinium oxide in a nanolaminate structure with other metal oxides, non-metal-containing dielectrics, or combinations thereof. The transition from one layer of the nanolaminate to another layer of the nanolaminate provides disruption to a tendency for an ordered structure in the nanolaminate stack. The term “nanolaminate” means a composite film of ultra thin layers of two or more materials in a layered stack. Typically, each layer in a nanolaminate has a thickness of an order of magnitude in the nanometer range. Further, each individual material layer of the nanolaminate may have a thickness as low as a monolayer of the material or as high as 20 nanometers. In an embodiment, an undoped GdOₓ/Zr-doped GdOₓ nanolaminate contains alternating layers of undoped gadolinium oxide and Zr-doped GdOₓ. In an embodiment, an ZrO_{y}/Zr-doped GdOₓ nanolaminate contains alternating layers of zirconium oxide and Zr-doped GdOₓ. In an embodiment, an undoped GdO_{z}/ZrO_{y}/Zr-doped GdOₓ nanolaminate contains various permutations of undoped gadolinium oxide layers, zirconium oxide layers, and zirconium-doped gadolinium oxide layers.

In an embodiment, dielectric structure 500 may be structured as a nanolaminate structure 500 including a zirconium-doped gadolinium oxide film structured as one or more monolayers. Nanolaminate structure 500 includes a plurality of layers 505-1, 505-2 . . . 505-N, where at least one layer contains a zirconium-doped gadolinium oxide film structured as one or more monolayers. The other layers may be insulating nitrides, insulating oxynitrides, and other dielectric materials such as insulating metal oxides. The sequencing of the layers depends on the application. The effective dielectric constant associated with nanolaminate structure 500 is that attributable to N capacitors in series, where each capacitor has a thickness defined by the thickness and composition of the corresponding layer. By selecting each thickness and the composition of each layer, a nanolaminate structure can be engineered to have a predetermined dielectric constant. Embodiments for structures such as nanolaminate structure 500 may be used as nanolaminate dielectrics in non-volatile read only memory (NROM) flash memory devices as well as other integrated circuits. In an embodiment, a layer of the nanolaminate structure 500 is used to store charge in the NROM device. The charge storage layer of a nanolaminate structure 500 in an NROM device may be a silicon oxide layer.

Transistors, capacitors, and other devices may include dielectric films containing a zirconium-doped gadolinium oxide layer structured as one or more monolayers. The zirconium-doped gadolinium oxide layer may be formed by atomic layer deposition. Dielectric films containing a zirconium-doped gadolinium oxide layer may be implemented into memory devices and electronic systems including information handling devices. Further, embodiments of electronic devices may be realized as integrated circuits. Embodiments of information handling devices may include wireless systems, telecommunication systems, and computers.

FIG. 6 illustrates a block diagram for an electronic system 600 having one or more devices having a dielectric structure including a Zr-doped GdOₓ film structured as one or more monolayers. Electronic system 600 includes a controller 605, a bus 615, and an electronic device 625, where bus 615 provides electrical conductivity between controller 605 and electronic device 625. In various embodiments, controller 605 may include an embodiment of a zirconium-doped gadolinium oxide film. In various embodiments, electronic device 625 may include an embodiment of a Zr-doped GdOₓ film. In various embodiments, controller 605 and electronic device 625 may include embodiments of a Zr-doped GdOₓ film. Electronic system 600 may include, but is not limited to, fiber optic systems, electro-optic systems, and information handling systems such as wireless systems, telecommunication systems, and computers.

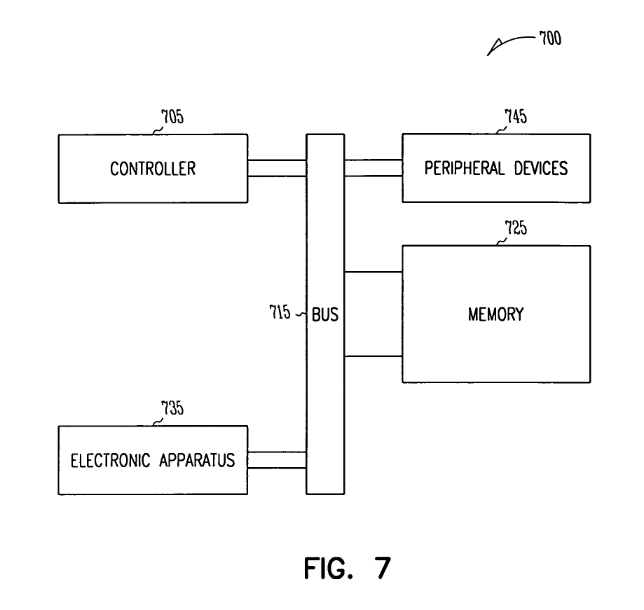

FIG. 7 depicts a diagram of an embodiment of a system 700 having a controller 705 and a memory 725. Controller 705 may include a zirconium-doped gadolinium oxide film structured as one or more monolayers. Memory 725 may include a zirconium-doped gadolinium oxide film structured as one or more monolayers. Controller 705 and memory 725 may include a zirconium-doped gadolinium oxide film structured as one or more monolayers. System 700 also includes an electronic apparatus 735 and a bus 715, where bus 715 provides electrical conductivity between controller 705 and electronic apparatus 735, and between controller 705 and memory 725. Bus 715 may include an address, a data bus, and a control bus, each independently configured. Alternatively, bus 715 may use common conductive lines for providing one or more of address, data, or control, the use of which is regulated by controller 705. In an embodiment, electronic apparatus 735 may be additional memory configured in a manner similar to memory 725. An embodiment may include an additional peripheral device or devices 745 coupled to bus 715. In an embodiment, controller 705 is a processor. One or more of controller 705, memory 725, bus 715, electronic apparatus 735, or peripheral devices 745 may include an embodiment of a dielectric layer having a zirconium-doped gadolinium oxide film structured as one or more monolayers. System 700 may include, but is not limited to, information handling devices, telecommunication systems, and computers.

Peripheral devices 745 may include displays, additional storage memory, or other control devices that may operate in conjunction with controller 705. Alternatively, peripheral devices 745 may include displays, additional storage memory, or other control devices that may operate in conjunction with memory 725 or controller 705 and memory 725.

Memory 725 may be realized as a memory device containing a zirconium-doped gadolinium oxide film structured as one or more monolayers. The zirconium-doped gadolinium oxide structure may be formed in a memory cell of a memory array. The zirconium-doped gadolinium oxide structure may be formed in a capacitor in a memory cell of a memory array. The zirconium-doped gadolinium oxide structure may be formed in a transistor in a memory cell of a memory array. It will be understood that embodiments are equally applicable to any size and type of memory circuit and are not intended to be limited to a particular type of memory device. Memory types include a DRAM, SRAM (Static Random Access Memory) or Flash memories. Additionally, the DRAM could be a synchronous DRAM commonly referred to as SGRAM (Synchronous Graphics Random Access Memory), SDRAM (Synchronous Dynamic Random Access Memory), SDRAM II, and DDR SDRAM (Double Data Rate SDRAM), as well as other emerging DRAM technologies.

Although specific embodiments have been illustrated and described herein, it will be appreciated by those of ordinary skill in the art that any arrangement that is calculated to achieve the same purpose may be substituted for the specific embodiments shown. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description.

What is claimed is:

1. A method comprising:
forming a zirconium-doped gadolinium oxide film in an integrated circuit on a substrate, including forming the zirconium-doped gadolinium oxide film by atomic layer deposition.

2. The method of claim 1, wherein forming the zirconium-doped gadolinium oxide film includes forming gadolinium oxide doped with zirconium having a zirconium content of 10% or less.

3. The method of claim 1, wherein forming the zirconium-doped gadolinium oxide film by atomic layer deposition includes forming the zirconium-doped gadolinium oxide film as an arrangement of zirconium-doped gadolinium oxide layers in which at least one zirconium-doped gadolinium oxide layer has a zirconium content different from the other zirconium-doped gadolinium oxide layers in the arrangement.

4. The method of claim 3, wherein forming the zirconium-doped gadolinium oxide film as an arrangement of zirconium-doped gadolinium oxide layers includes forming the arrangement with a zirconium-doped gadolinium oxide layer of highest zirconium content at an interface to material on which the zirconium-doped gadolinium oxide film is disposed.

5. The method of claim 1, wherein forming the zirconium-doped gadolinium oxide film includes forming gadolinium oxide doped with zirconium with a dielectric constant in the range from about 15 to about 25.

6. The method of claim 1, wherein forming the zirconium-doped gadolinium oxide film by atomic layer deposition includes using a Gd(thd)₃ (thd=2,2,6,6-tetramethyl-3,5-heptanedione) precursor in the atomic layer deposition.

7. The method of claim 1, wherein forming the zirconium-doped gadolinium oxide film by atomic layer deposition includes using a tetrakis(diethylamino)zirconium precursor in the atomic layer deposition.

8. The method of claim 1, wherein forming the zirconium-doped gadolinium oxide film by atomic layer deposition includes using a zirconium tertiary-butoxide precursor in the atomic layer deposition.

9. The method of claim 1, wherein forming the zirconium-doped gadolinium oxide film by atomic layer deposition includes using a zirconium halide precursor in the atomic layer deposition.

10. The method of claim 9, wherein using a zirconium halide precursor includes using a zirconium chloride precursor in the atomic layer deposition.

11. The method of claim 1, wherein the method includes forming a transistor having the zirconium-doped gadolinium oxide film as a gate dielectric.

12. The method of claim 1, wherein the method includes forming a capacitor having the zirconium-doped gadolinium oxide film as a capacitor dielectric.

13. The method of claim 1, wherein the method includes forming a memory device containing the zirconium-doped gadolinium oxide film.

14. The method of claim 1, wherein the method includes forming a conductive path to a conductive layer contacting the zirconium-doped gadolinium oxide film to provide a signal to the conductive layer to operate in an electronic system.

15. A method comprising:
forming a first electrode on a substrate;
forming a dielectric layer containing a zirconium-doped gadolinium oxide film, the dielectric layer disposed on and contacting the first electrode, including forming the zirconium-doped gadolinium oxide film by atomic layer deposition, wherein forming the zirconium-doped gadolinium oxide film by atomic layer deposition includes using an atomic layer deposition cycle having a number of gadolinium sequences and a number of zirconium sequences, the number of gadolinium sequences and the number of zirconium sequences selected to provide the zirconium-doped gadolinium oxide film with a predetermined zirconium content; and
forming a second electrode on and contacting the dielectric layer.

16. The method of claim 15, wherein forming a dielectric layer includes forming the zirconium-doped gadolinium oxide film as the dielectric layer.

17. The method of claim 15, wherein forming the zirconium-doped gadolinium oxide film by atomic layer deposition includes using a Gd(thd)₃ (thd=2,2,6,6-tetramethyl-3,5-heptanedione) precursor in the atomic layer deposition.

18. The method of claim 15, wherein forming the zirconium-doped gadolinium oxide film by atomic layer deposition includes using a tetrakis(diethylamino)zirconium precursor in the atomic layer deposition.

19. The method of claim 15, wherein the method includes forming a dynamic random access memory having the first electrode, the dielectric layer, and the second electrode as a capacitor in the dynamic random access memory.

20. The method of claim 15, wherein the method includes forming an analog integrated circuit having the first electrode, the dielectric layer, and the second electrode as a capacitor in the analog integrated circuit.

21. The method of claim 15, wherein the method includes forming a radio frequency integrated circuit having the first electrode, the dielectric layer, and the second electrode as a capacitor in the radio frequency integrated circuit.

22. The method of claim 15, wherein the method includes forming a mixed signal integrated circuit having the first electrode, the dielectric layer, and the second electrode as a capacitor in the mixed signal integrated circuit.

23. The method of claim 15, wherein forming a dielectric layer includes forming the dielectric layer having multiple layers of dielectrics within which the zirconium-doped gadolinium oxide film is disposed.

24. The method of claim 23, wherein forming the dielectric layer having multiple layers of dielectrics includes forming a nanolaminate.

25. The method of claim 15, wherein forming the zirconium-doped gadolinium oxide film includes forming gadolinium oxide doped with zirconium having a zirconium content of 10% or less.

26. A method comprising;
forming a source and a drain of a transistor, the source and the drain separated by a channel;
forming a dielectric layer above the channel, the dielectric layer containing a zirconium-doped gadolinium oxide film, including forming the zirconium-doped gadolinium oxide film by atomic layer deposition; and
forming a gate above the dielectric layer.

27. The method of claim 26, wherein forming a dielectric layer includes forming the zirconium-doped gadolinium oxide film as the dielectric layer.

28. The method of claim 26, wherein forming the zirconium-doped gadolinium oxide film by atomic layer deposition includes using an atomic layer deposition cycle having more than five times as many gadolinium sequences as zirconium sequences.

29. The method of claim 26, wherein forming the zirconium-doped gadolinium oxide film by atomic layer deposition includes forming the zirconium-doped gadolinium oxide film as an arrangement of zirconium-doped gadolinium oxide layers in which at least one zirconium-doped gadolinium oxide layer has a zirconium content different from the other zirconium-doped gadolinium oxide layers in the arrangement.

30. The method of claim 29, wherein forming the zirconium-doped gadolinium oxide film as an arrangement of zirconium-doped gadolinium oxide layers includes forming the arrangement with a zirconium-doped gadolinium oxide layer of highest zirconium content contacting the channel.

31. The method of claim 29, wherein forming the zirconium-doped gadolinium oxide film as an arrangement of zirconium-doped gadolinium oxide layers includes forming the arrangement with a zirconium-doped gadolinium oxide layer of highest zirconium content contacting a floating gate.

32. The method of claim 26, wherein forming the zirconium-doped gadolinium oxide film by atomic layer deposition includes using a Gd(thd)₃ (thd=2,2,6,6-tetramethyl-3,5-heptanedione) precursor in the atomic layer deposition.

33. The method of claim 26, wherein forming the zirconium-doped gadolinium oxide film by atomic layer deposition includes using a zirconium tertiary-butoxide precursor in the atomic layer deposition.

34. The method of claim 26, wherein forming the zirconium-doped gadolinium oxide film includes forming gadolinium oxide doped with zirconium having a zirconium content of 10% or less.

35. The method of claim 26, wherein the method includes forming the dielectric layer as a gate insulator in a silicon CMOS transistor.

36. The method of claim 26, wherein forming a dielectric layer includes forming the dielectric layer as a gate dielectric contacting the channel.

37. The method of claim 26, wherein forming a dielectric layer includes forming the dielectric layer as a tunnel gate insulator contacting the channel.

38. The method of claim 26, wherein forming a dielectric layer includes forming the dielectric layer on and contacting a floating gate.

39. The method of claim 26, wherein the method includes forming the dielectric layer as a tunnel insulator contacting the channel and forming a floating gate dielectric on and contacting a floating gate, the floating gate dielectric containing a zirconium-doped gadolinium oxide film.

40. A method comprising:
forming an array of memory cells in a substrate, a memory cell having a dielectric layer containing a zirconium-doped gadolinium oxide film, including forming the zirconium-doped gadolinium oxide film by atomic layer deposition.

41. The method of claim 40, wherein forming a dielectric layer includes forming the zirconium-doped gadolinium oxide film as the dielectric layer.

42. The method of claim 40, wherein forming the zirconium-doped gadolinium oxide film by atomic layer deposition includes forming the zirconium-doped gadolinium oxide film as an arrangement of zirconium-doped gadolinium oxide layers in which at least one zirconium-doped gadolinium oxide layer has a zirconium content different from the other zirconium-doped gadolinium oxide layers in the arrangement.

43. The method of claim 42, wherein forming the zirconium-doped gadolinium oxide film as an arrangement of zirconium-doped gadolinium oxide layers includes forming the arrangement with a zirconium-doped gadolinium oxide layer of highest zirconium content contacting an electrode of a capacitor in a memory cell.

44. The method of claim 42, wherein forming the zirconium-doped gadolinium oxide film as an arrangement of zirconium-doped gadolinium oxide layers includes forming the arrangement with a zirconium-doped gadolinium oxide layer of highest zirconium content contacting a channel of a transistor in a memory cell.

45. The method of claim 42, wherein forming the zirconium-doped gadolinium oxide film as an arrangement of zirconium-doped gadolinium oxide layers includes forming the arrangement with a zirconium-doped gadolinium oxide layer of highest zirconium content contacting a floating gate of a floating gate transistor in a memory cell.

46. The method of claim 40, wherein forming the zirconium-doped gadolinium oxide film by atomic layer deposition includes using a Gd(thd)₃ (thd=2,2,6,6-tetramethyl-3,5-heptanedione) precursor in the atomic layer deposition.

47. The method of claim 40, wherein forming the zirconium-doped gadolinium oxide film by atomic layer deposition includes using a zirconium halide precursor in the atomic layer deposition.

48. The method of claim 40, wherein forming the zirconium-doped gadolinium oxide film includes forming gadolinium oxide doped with zirconium having a zirconium content of 10% or less.

49. The method of claim 40, wherein the method includes forming the dielectric layer as a gate insulator of a transistor in a memory device.

50. The method of claim 40, wherein the method includes forming the dielectric layer as a tunnel gate insulator in a flash memory.

51. The method of claim 40, wherein the method includes forming the dielectric layer as an inter-gate insulator in a flash memory.

52. The method of claim 40, wherein the method includes forming the dielectric layer as a capacitor dielectric of a capacitor in a memory cell.

53. The method of claim 40, wherein the method includes forming a dynamic random access memory.

54. The method of claim 40, wherein the method includes forming the dielectric layer as a nanolaminate dielectric.

55. The method of claim 40, wherein the method includes forming the dielectric layer as a nanolaminate dielectric in a NROM flash memory.

56. A method comprising:
providing a controller;
coupling an integrated circuit to the controller, wherein the integrated circuit includes a dielectric layer containing a zirconium-doped gadolinium oxide layer, the zirconium-doped gadolinium oxide layer formed by atomic layer deposition.

57. The method of claim 56, wherein forming a dielectric layer includes forming the zirconium-doped gadolinium oxide film as the dielectric layer.

58. The method of claim 56, wherein forming the zirconium-doped gadolinium oxide film by atomic layer deposition includes using a Gd(thd)₃ (thd=2,2,6,6-tetramethyl-3,5-heptanedione) precursor and using a zirconium chloride precursor.

59. The method of claim 56, wherein forming the zirconium-doped gadolinium oxide film by atomic layer deposition includes forming the zirconium-doped gadolinium oxide film as an arrangement of zirconium-doped gadolinium oxide layers in which at least one zirconium-doped gadolinium oxide layer has a zirconium content different from the other zirconium-doped gadolinium oxide layers in the arrangement.

60. The method of claim 59, wherein forming the zirconium-doped gadolinium oxide film as an arrangement of zirconium-doped gadolinium oxide layers includes forming the arrangement with a zirconium-doped gadolinium oxide layer of highest zirconium content contacting a silicon-based region of a device in the integrated circuit.

61. The method of claim 56, wherein forming the zirconium-doped gadolinium oxide film includes forming gadolinium oxide doped with zirconium having a zirconium content of 10% or less.

62. The method of claim 56, wherein coupling an integrated circuit to the controller includes coupling a memory device formed as the integrated circuit.

63. The method of claim 56, wherein providing a controller includes providing a processor.

64. The method of claim 56, wherein coupling an integrated circuit to the controller includes coupling a mixed signal integrated circuit formed as the integrated circuit.

65. The method of claim 56, wherein the method includes forming an information handling system.

66. The method of claim 65, wherein forming an information handling system includes forming a wireless system.

67. An electronic device comprising:
a substrate; and
a dielectric layer in an integrated circuit on the substrate, the dielectric layer containing a zirconium-doped gadolinium oxide film, the zirconium-doped gadolinium oxide film structured as one or more monolayers.

68. The electronic device of claim 67, wherein the dielectric layer includes the zirconium-doped gadolinium oxide film as the dielectric layer.

69. The electronic device of claim 67, wherein the zirconium-doped gadolinium oxide film includes an arrangement of zirconium-doped gadolinium oxide layers in which at least one zirconium-doped gadolinium oxide layer has a zirconium content different from the other zirconium-doped gadolinium oxide layers in the arrangement.

70. The electronic device of claim 69, wherein the arrangement of zirconium-doped gadolinium oxide layers includes a zirconium-doped gadolinium oxide layer of highest zirconium content at an interface to material on which the zirconium-doped gadolinium oxide film is disposed.

71. The electronic device of claim 69, wherein the arrangement of zirconium-doped gadolinium oxide layers includes a zirconium-doped gadolinium oxide layer of highest zirconium content contacting a silicon-based region of a device in the integrated circuit.

72. The electronic device of claim 67, wherein the zirconium-doped gadolinium oxide film has a zirconium content of 10% or less.

73. The electronic device of claim 67, wherein the dielectric layer is configured as a capacitor dielectric.

74. The electronic device of claim 67, wherein the electronic device includes a transistor having the dielectric layer as a gate insulator of the transistor.

75. The electronic device of claim 67, wherein the electronic device includes a CMOS transistor having the dielectric layer as a gate insulator.

76. The electronic device of claim 67, wherein the electronic device includes a floating gate transistor having the dielectric layer as a floating gate insulator of the floating gate transistor.

77. The electronic device of claim 67, wherein the electronic device includes a memory having the dielectric layer as a capacitor dielectric in the memory.

78. The electronic device of claim 67, wherein the electronic device includes a memory having the dielectric layer configured as a nanolaminate in the memory.

79. The electronic device of claim 67, wherein the electronic device includes a conductive path to a conductive layer on and contacting the dielectric layer to provide a signal to the conductive layer to operate in an electronic system.
